(19) United States
(12) Patent Application Publication
(10) Pub. No.: US 2016/0049303 A1
(43) Pub. Date: Feb. 18, 2016

(54) METHOD FOR FORMING A MEMORY STRUCTURE HAVING NANOCRYSTALS

(71) Applicants: EUHNGI LEE, Austin, TX (US); CHEONG M. HONG, Austin, TX (US); SUNG-TAEG KANG, Austin, TX (US); MARC A. ROSSOW, Austin, TX (US)

(72) Inventors: EUHNGI LEE, Austin, TX (US); CHEONG M. HONG, Austin, TX (US); SUNG-TAEG KANG, Austin, TX (US); MARC A. ROSSOW, Austin, TX (US)

(73) Assignee: FREESCALE SEMICONDUCTOR, INC., Austin, TX (US)

(21) Appl. No.: 14/457,556

(22) Filed: Aug. 12, 2014

(51) Int. Cl. H01L 21/28; H01L 21/285

(52) U.S. Cl. CPC H01L 21/28282; H01L 21/28525

(57) ABSTRACT

A method of forming a semiconductor structure uses a substrate. A first insulating layer is formed over the substrate. An amorphous silicon layer is formed over the first insulating layer. Heat is applied to the amorphous silicon layer to form a plurality of seed nanocrystals over the first insulating layer. Silicon is epitaxially grown on the plurality of seed nanocrystals to leave resulting nanocrystals.

### BACKGROUND

1. Field

This disclosure relates generally to semiconductor processing, and more specifically, to a method for forming a memory structure having nanocrystals.

2. Related Art

In one type of nonvolatile memory structure, nanocrystals are used as the charge storage element. However, as processing technology advances and semiconductor devices become increasingly smaller, fewer nanocrystals fit within each bit cell, which affects the charge storage capabilities. With fewer nanocrystals, the uniformity and quality of nanocrystals becomes increasingly important for memory performance and reliability. Therefore, it is desirable to increase nanocrystal uniformity and quality which allows for improved memory performance and reliability.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates, in cross section form, a memory structure at a first processing stage, in accordance with one embodiment of the present invention.

FIG. 2 illustrates, in cross section form, the memory structure of FIG. 1 at a subsequent processing stage, in accordance with one embodiment of the present invention.

FIG. 3 illustrates, in cross section form, the memory structure of FIG. 2 at a subsequent processing stage, in accordance with one embodiment of the present invention.

FIG. 4 illustrates, in cross section form, the memory structure of FIG. 3 at a subsequent processing stage, in accordance with one embodiment of the present invention.

### DETAILED DESCRIPTION

In order to improve nanocrystal uniformity, a thin layer of amorphous silicon is deposited and subsequently annealed to form a layer of uniform seed nanocrystals. A layer of silicon is then epitaxially grown on the seed nanocrystals to form a layer of resulting nanocrystals. The resulting nanocrystals are substantially uniform in size and have a substantially monocrystalline outer layer.

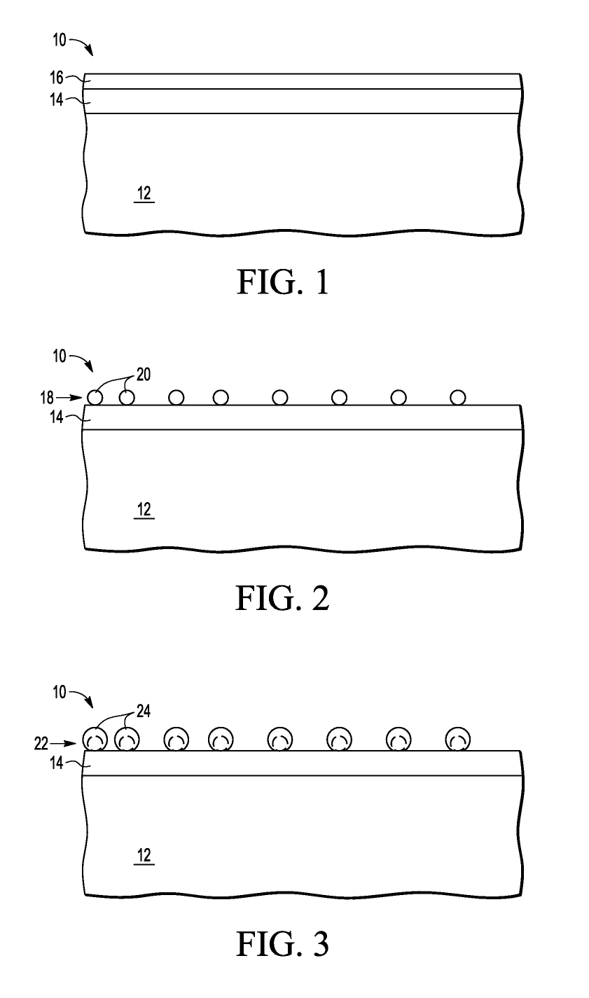

FIG. 1 illustrates, in cross sectional form, a semiconductor structure 10 in accordance with one embodiment of the present invention. Semiconductor structure 10 includes a semiconductor substrate 12, a dielectric layer 14 over substrate 12, and an amorphous silicon layer 16 over dielectric layer 14. Substrate 12 can be any semiconductor material or combinations of materials, such as gallium arsenide, silicon germanium, silicon-on-insulator (SOI), silicon, monocrystalline silicon, the like, and combinations of the above. In one embodiment, dielectric layer 14 (also referred to as an insulating layer) is an oxide and may be referred to as a bottom oxide layer. Amorphous silicon layer 16 has a thickness of 10 nanometers or less.

FIG. 2 illustrates, in cross sectional form, semiconductor structure 10 after an anneal. In one embodiment, for the anneal, heat is applied at temperature in excess of 700 degrees Celsius. In one embodiment, heat is applied at a temperature of at least 800 degrees Celsius. In yet another embodiment, heat is applied at a temperature of at least 850 degrees Celsius. During the anneal, semiconductor layer 18 undergoes an agglomeration process resulting in nanocrystals. Therefore, as a result of the anneal, a seed nanocrystal layer 18 is formed over dielectric layer 14, which includes a plurality of nanocrystals 20. Nanocrystals 20 are crystalline polysilicon. Further, the nanocrystals of seed nanocrystal layer 20 are substantially uniform, in that they are substantially similar in size. The anneal at higher temperatures, such as at at least 800 degrees Celsius, reduces the distribution of thickness of seed nanocrystals 20. This uniformity in size may also result in increased uniformity in spacing between adjacent nanocrystals. Note that the level of heat applied affects the density of seed nanocrystal layer 18, therefore, the anneal temperature may be selected to result in a desired density of seed nanocrystals layer 18 (which determines the density of the resulting nanocrystals layer, described below).

FIG. 3 illustrates, in cross sectional form, semiconductor structure 10 after epitaxially growing silicon on seed nanocrystals layer 18 resulting in nanocrystals layer 22, also referred to as the resulting nanocrystals layer. Therefore, silicon is grown on each nanocrystal 20 in seed nanocrystal layer 18 to form resulting nanocrystals 24. Note that a dotted line boundary is illustrated in FIG. 3 which represents the original seed nanocrystals of seed nanocrystal layer 18. However, note that this boundary may not be visible between the original seed nanocrystals and the epitaxially grown silicon. In one embodiment, an inner portion of resulting nanocrystals 24, corresponding to the original seed nanocrystal, is crystalline polysilicon that is substantially spherical while an outer portion of resulting nanocrystals 24 is substantially monocrystalline silicon. The epitaxial growing of the silicon may form a substantially monocrystalline silicon layer that has thickness that, when added to the seed nanocrystals 20, results in a desired total thickness of resulting nanocrystal layer 22. In one embodiment, the thickness of the epitaxially grown silicon layer on seed nanocrystals 20 is greater than the thickness of amorphous silicon layer 16. Note that the resulting nanocrystals in nanocrystal layer 22 maintain the uniformity achieved during the formation of seed nanocrystal layer 18. Therefore, resulting nanocrystals 24 are substantially similar in size since the thickness of the epitaxially grown silicon layer is substantially the same for each resulting nanocrystal 24. This uniformity in size may also result in increased uniformity in spacing between adjacent nanocrystals. Also, epitaxially grown silicon is highly selective and thus grows only on the nanocrystals of seed nanocrystal layer 18 and does not generally form new or additional nanocrystals. That is, the epitaxially growing of silicon avoids silicon formation on dielectric layer 14 between resulting nanocrystals 24. As mentioned above, the density of seed nanocrystals layer 18 determines the density of resulting nanocrystal layer 22.

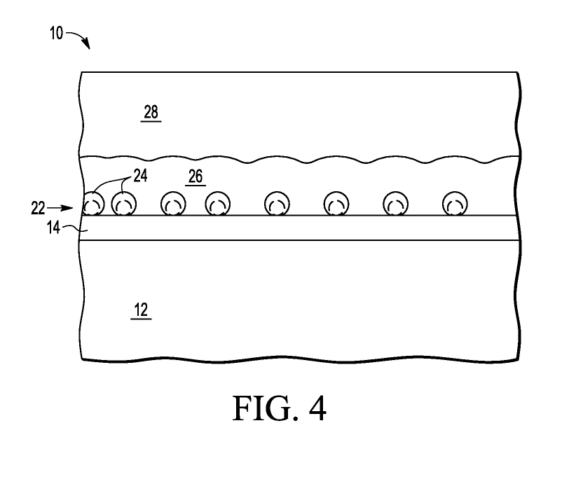

FIG. 4 illustrates, in cross sectional form, semiconductor structure 10 after formation of a dielectric layer 26 over nanocrystal layer 22, and a conductive layer 28 over dielectric layer 26. Dielectric layer 26 is formed over and among nanocrystals 24, and may also be referred to as an insulating layer. Additional processing may be performed to form a completed memory device in which conductive layer 28 corresponds to a gate layer and resulting nanocrystal layer 22 is used as the non-volatile storage element. For example, conductive layer 28 may be subsequently patterned to form a gate (also referred to as a gate electrode), and various doping steps may be performed to form source/drain regions. Semiconductor structure 10 may be used to form, for example, a split gate memory cell having a control gate and a select gate, as known in the art. Due to the improved uniformity achieved for resulting nanocrystal layer 22, note that a well-controlled size distribution of nanocrystals may be achieved across bitcells of a memory device.

Therefore, by now it can be appreciated that by initially forming a seed nanocrystal layer, in which smaller and substantially uniform nanocrystals are formed, uniformity may be maintained during subsequent epitaxial growth of silicon onto the seed nanocrystals. In this manner, the resulting nanocrystal layer is more uniform as compared to conventional nanocrystal formation which uses multiple silicon deposition/anneal steps in which after each silicon deposition step, an anneal is performed to agglomerate the silicon. This conventional nanocrystal formation results in greatly non-uniform nanocrystals which negatively impacts performance and reliability of a nonvolatile memory. However, by forming a highly uniform seed nanocrystals layer followed by epitaxially growing silicon on each seed nanocrystals, improved uniformity and nanocrystals quality can be achieved, which may result in improved memory performance and reliability.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. For example, different types of non-volatile memory devices utilizing the resulting nanocrystal layer as the charge storage element may be formed. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

The following are various embodiments of the present invention.

In one embodiment, a method of forming a semiconductor structure using a substrate, includes forming a first insulating layer over the substrate; forming an amorphous silicon layer over the first insulating layer; applying heat to the amorphous silicon layer to form a plurality of seed nanocrystals over the first insulating layer; and epitaxially growing silicon on the plurality of seed nanocrystals to leave resulting nanocrystals. In one aspect of the above embodiment, the method further includes forming a second insulating layer over and among the resulting nanocrystals. In a further aspect of the above embodiment, the method further includes forming a conductive layer over the second insulating layer. In yet a further aspect of the above embodiment, the forming the conductive layer forms a gate conductor for a memory structure. In another aspect of the above embodiment, the epitaxially growing is further characterized as forming resulting nanocrystals that are substantially monocrystalline silicon in an outer portion of the resulting nanocrystals. In another aspect, the applying heat is further characterized as heating to a temperature in excess of 700 degrees Celsius. In another aspect, the applying heat is further characterized as heating to a temperature of at least 800 degrees Celsius. In another aspect, the forming the amorphous silicon layer is further characterized as forming the amorphous silicon layer to a thickness less than 100 Angstroms. In a further aspect, the epitaxially growing silicon is further characterized as forming a substantially monocrystalline silicon layer that has a thickness that, when added to the thickness of the amorphous silicon layer, results in a desired total thickness of resulting nanocrystals. In yet another aspect of the above embodiment, the applying heat results in a density of a desired density of resulting nanocrystals formed from the epitaxial growing. In another aspect, the epitaxilly growing forms resulting nanocrystals that are substantially monocrystalline, and the method further includes forming a memory structure using the resulting nanocrystals as a non-volatile storage element. In another aspect of the above embodiment, the method further includes selecting a thickness of the amorphous silicon layer resulting from the forming the amorphous silicon layer and selecting a temperature used in the heating to result in a desired resulting nanocrystal density after the epitaxially growing.

In another embodiment, a semiconductor structure includes a semiconductor substrate; a first insulating layer over the semiconductor substrate; and a plurality of silicon nanocrystals over the first insulating layer, wherein each silicon nanocrystal layer of the plurality of nanocrystals has a substantially monocrystalline outer layer. In one aspect of the above another embodiment, each of the silicon nanocrystals have an inner crystalline portion that is substantially spherical. In another aspect, the structure further includes a second insulating layer over and among the plurality of nanocrystals; and a conductive layer over the second insulating layer.

In yet another embodiment, a method of forming a semiconductor structure using a substrate includes forming a first insulating layer over the substrate; forming a layer of amorphous silicon of a first thickness on the first insulating layer; annealing the layer of amorphous silicon to form a plurality of crystalline polysilicon nanocrystals on the first insulating layer; epitaxially growing a layer of silicon of a second thickness greater than the first thickness on the plurality of crystalline polysilicon nanocrystals to form resulting nanocrystals, wherein the epitaxially growing avoids formation of silicon on the first insulating layer between the resulting nanocrystals. In one aspect of the above yet another embodiment, the epitaxially growing is further characterized by the layer of silicon being a layer of monocrystalline silicon. In another aspect, the forming the layer of amorphous silicon is further characterized by the amorphous silicon having a first thickness; and the epitaxially growing is further characterized by the layer of silicon having a second thickness greater than the first thickness. In a further aspect, the annealing is performed at a temperature of at least 800 degrees Celsius to reduce the distribution of thicknesses of the crystalline polysilicon nanocrystals. In yet a further aspect, the epitaxially growing is further characterized by the second thickness being substantially the same for each resulting nanocrystal of the plurality of nanocrystals.

What is claimed is:

1. A method of forming a semiconductor structure using a substrate, comprising:
forming a first insulating layer over the substrate;
forming an amorphous silicon layer over the first insulating layer;
applying heat to the amorphous silicon layer to form a plurality of seed nanocrystals over the first insulating layer; and
epitaxially growing silicon on the plurality of seed nanocrystals to leave resulting nanocrystals.

2. The method of claim 1, further comprising:
forming a second insulating layer over and among the resulting nanocrystals.

3. The method of claim 2, further comprising:
forming a conductive layer over the second insulating layer.

4. The method of claim 3, wherein the forming the conductive layer forms a gate conductor for a memory structure.

5. The method of claim 1, wherein:
the epitaxially growing is further characterized as forming resulting nanocrystals that are substantially monocrystalline silicon in an outer portion of the resulting nanocrystals.

6. The method of claim 1, wherein:
the applying heat is further characterized as heating to a temperature in excess of 700 degrees Celsius.

7. The method of claim 1, wherein.
the applying heat is further characterized as heating to a temperature of at least 800 degrees Celsius.

8. The method of claim 1, wherein:
the forming the amorphous silicon layer is further characterized as forming the amorphous silicon layer to a thickness less than 100 Angstroms.

9. The method of claim 8, wherein:
the epitaxially growing silicon is further characterized as forming a substantially monocrystalline silicon layer that has a thickness that, when added to the thickness of the amorphous silicon layer, results in a desired total thickness of resulting nanocrystals.

10. A method of claim 1, wherein:
the applying heat results in a density of a desired density of resulting nanocrystals formed from the epitaxial growing.

11. The method of claim 1, wherein the epitaxilly growing forms resulting nanocrystals that are substantially monocrystalline, further comprising:
forming a memory structure using the resulting nanocrystals as a non-volatile storage element.

12. The method of claim 1, further comprising selecting a thickness of the amorphous silicon layer resulting from the forming the amorphous silicon layer and selecting a temperature used in the heating to result in a desired resulting nanocrystal density after the epitaxially growing.

13. A semiconductor structure, comprising:
a semiconductor substrate;
a first insulating layer over the semiconductor substrate; and
a plurality of silicon nanocrystals over the first insulating layer, wherein each silicon nanocrystal layer of the plurality of nanocrystals has a substantially monocrystalline outer layer.

14. The semiconductor structure of claim 13, wherein each of the silicon nanocrystals have an inner crystalline portion that is substantially spherical.

15. The semiconductor structure of claim 13 further comprising:
a second insulating layer over and among the plurality of nanocrystals; and
a conductive layer over the second insulating layer.

16. A method of forming a semiconductor structure using a substrate, comprising:
forming a first insulating layer over the substrate;
forming a layer of amorphous silicon of a first thickness on the first insulating layer;
annealing the layer of amorphous silicon to form a plurality of crystalline polysilicon nanocrystals on the first insulating layer;
epitaxially growing a layer of silicon of a second thickness greater than the first thickness on the plurality of crystalline polysilicon nanocrystals to form resulting nanocrystals, wherein the epitaxially growing avoids formation of silicon on the first insulating layer between the resulting nanocrystals.

17. The method of claim 16, wherein:
the epitaxially growing is further characterized by the layer of silicon being a layer of monocrystalline silicon.

18. The method of claim 17, wherein:
the forming the layer of amorphous silicon is further characterized by the amorphous silicon having a first thickness; and
the epitaxially growing is further characterized by the layer of silicon having a second thickness greater than the first thickness.

19. The method of claim 18, wherein:
the annealing is performed at a temperature of at least 800 degrees Celsius to reduce the distribution of thicknesses of the crystalline polysilicon nanocrystals.

20. The method of claim 19, wherein:
the epitaxially growing is further characterized by the second thickness being substantially the same for each resulting nanocrystal of the plurality of nanocrystals.
